(19) United States
(12) Patent Application Publication
(10) Pub. No.: US 2017/0212183 A1
(43) Pub. Date: Jul. 27, 2017

(54) METHOD FOR RESOLVING NATURAL SENSOR AMBIGUITY FOR DNV DIRECTION FINDING APPLICATIONS

(71) Applicant: Lockheed Martin Corporation, Bethesda, MD (US)

(72) Inventors: Laird Nicholas Egan, Philadelphia, PA (US); Emanuel Solomon Stockman, Philadelphia, PA (US)

(73) Assignee: Lockheed Martin Corporation, Bethesda, MD (US)

(21) Appl. No.: 15/003,678

(22) Filed: Jan. 21, 2016

(51) Int. Cl. G01R 33/032

(52) U.S. Cl. CPC G01R 33/032

(57) ABSTRACT

A system for unambiguously determines a signed magnetic field vector from a magneto-optical defect center magnetic field sensor. The magneto-optical magnetic field sensor may include a diamond nitrogen vacancy material.

### CROSS-REFERENCE TO RELATED PATENT APPLICATIONS

The present application is related to co-pending U.S. application Ser. No. ______, Attorney Docket No. 111423-1046, filed Jan. 21, 2016, titled “APPARATUS AND METHOD FOR RECOVERY OF THREE DIMENSIONAL MAGNETIC FIELD FROM A MAGNETIC DETECTION SYSTEM”, which is incorporated by reference herein in its entirety.

### BACKGROUND

The present disclosure generally relates to the field of magnetometers, such as methods and systems for resolving the natural ambiguity of diamond nitrogen vacancy magnetic sensors.

### SUMMARY

Some embodiments relate to a system. The system may comprise a nitrogen vacancy (NV) diamond material comprising a plurality of NV centers; a magnetic field source; a radio frequency (RF) excitation source configured to provide RF excitation to the NV diamond material; an optical excitation source configured to provide optical excitation to the NV diamond material; an optical detector configured to receive an optical signal emitted by the NV diamond material; and a controller. The controller may be configured to control the RF excitation source to provide pulsed RF excitation to the NV diamond material, and determine a sign of the magnetic field vector at the NV diamond material based on a received light detection signal from the optical detector. The controller may be configured to control the optical excitation source to provide continuous wave optical excitation to the NV diamond. The controller may be further configured to identify Lorentzian peaks in a received light detection signal from the optical detector as a function of RF excitation frequency. The controller may be configured to determine a sign of the magnetic field vector based on an equilibration time for a pair of the identified Lorentzian peaks.

Other embodiments relate to a system. The system may comprise a magneto-optical defect center material; a magnetic field source; a radio frequency (RF) excitation source configured to provide RF excitation to the magneto-optical defect center material; an optical excitation source configured to provide optical excitation to the magneto-optical defect center material; an optical detector configured to receive an optical signal emitted by the magneto-optical defect center material; and a controller. The controller may be configured to control the RF excitation source to provide pulsed RF excitation to the magneto-optical defect center material, control the optical excitation source to provide optical excitation to the magneto-optical defect center material, and determine a sign of the magnetic field vector at the magneto-optical defect center material based on a received light detection signal from the optical detector. The controller may be configured to control the optical excitation source to provide continuous wave optical excitation to the magneto-optical defect center material. The controller may be further configured to identify Lorentzian peaks in a received light detection signal from the optical detector as a function of RF excitation frequency. The controller may be configured to determine a sign of the magnetic field vector based on an equilibration time for a pair of the identified Lorentzian peaks.

Other embodiments relate to a system. The system may comprise a nitrogen vacancy (NV) diamond material comprising a plurality of NV centers; a magnetic field source; a radio frequency (RF) excitation source configured to provide RF excitation to the NV diamond material; an optical excitation source configured to provide optical excitation to the NV diamond material; an optical detector configured to receive an optical signal emitted by the NV diamond material; and a controller. The controller may be configured to determine a first equilibration time for a first peak of a Lorentzian pair based on a received light detection signal from the optical detector, determine a second equilibration time for a second peak of the Lorentzian pair based on a received light detection signal from the optical detector, and determine a sign of the magnetic field vector at the NV diamond material based on the first equilibration time and the second equilibration time. The controller may be configured to assign a positive spin state to the peak of the Lorentzian pair with the longer equilibration time. The first equilibration time and the second equilibration time may be determined by measuring the time to reach 60% of a normalized equilibrium intensity after the beginning of an RF pulse, wherein the normalized equilibrium intensity is determined based on the intensity in the absence of the RF pulse and the equilibrium intensity in the presence of the RF pulse.

### BRIEF DESCRIPTION OF THE DRAWINGS

FIG. 1 illustrates one orientation of a NV center in a diamond lattice.

FIG. 2 is an energy level diagram illustrates energy levels of spin states for the NV center.

FIG. 3 is a schematic illustrating a NV center magnetic sensor system.

FIG. 4 is a graph illustrating the fluorescence as a function of applied RF frequency of an NV center along a given direction for a zero magnetic field and a non-zero magnetic field.

FIG. 5 is a graph illustrating the fluorescence as a function of applied RF frequency for four different NV center orientations for a non-zero magnetic field.

FIG. 6 is a schematic illustrating a NV center magnetic sensor system according to some embodiments.

FIG. 7 is graphs illustrating the fluorescence as a function of applied RF frequency of four different NV center orientations for a magnetic field applied in opposite directions to the NV center diamond material.

FIG. 8 is a graph illustrating the fluorescence intensity as a function of time for a NV center diamond material with a pulsed RF excitation.

FIG. 9 is a graph illustrating the fluorescence as a function of applied RF frequency of four different NV center orientations for a magnetic field applied in opposite directions to the NV center diamond material, with a Lorentzian pair being identified in the graph.

FIG. 10 is a graph illustrating the fluorescence intensity as a function of time for a NV center diamond material for a pulse of RF excitation.

FIG. 11 is a graph illustrating the normalized fluorescence intensity as a function of time for a pair of Lorentzian peaks of a NV center diamond material.

FIG. 12 is a graph illustrating the time to 60% of the equilibrium fluorescence as a function of RF frequency for a negative and positive magnetic bias field applied to a NV center diamond material.

### DETAILED DESCRIPTION

It is possible to resolve a magnetic field vector from a diamond nitrogen vacancy magnetic field sensor. The method of determining the sign of the magnetic field vector resolved by the DNV magnetic field sensor described herein may resolve a natural ambiguity of the magnetic field sensor with regard to the sign of the vector. The ability to resolve the sign of the resolved magnetic field vector expands the applications in which the DNV magnetic field sensor may be employed.

NV Center, its Electronic Structure, and Optical and RF Interaction

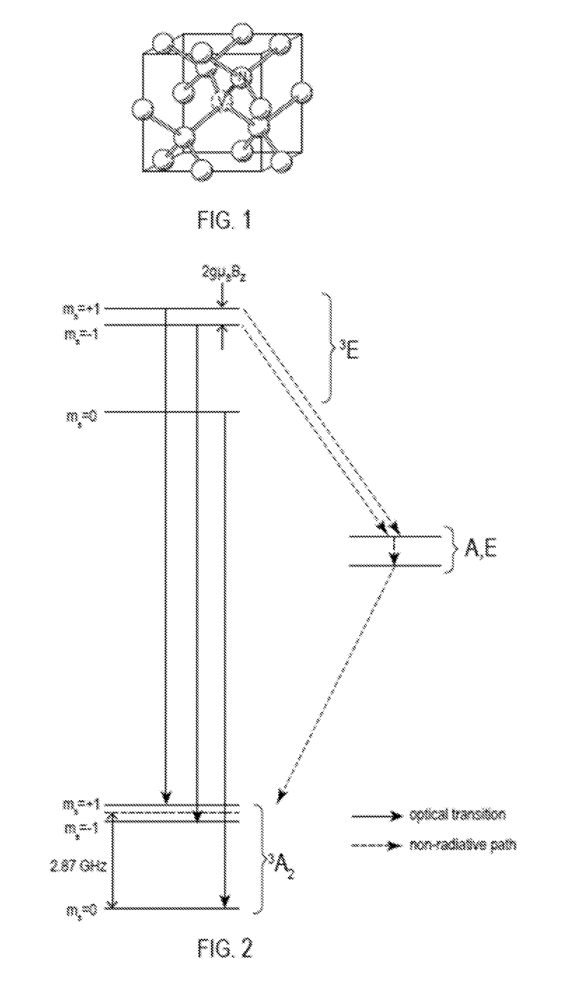

The nitrogen vacancy (NV) center in diamond comprises a substitutional nitrogen atom in a lattice site adjacent a carbon vacancy as shown in FIG. 1. The NV center may have four orientations, each corresponding to a different crystallographic orientation of the diamond lattice.

The NV center may exist in a neutral charge state or a negative charge state. Conventionally, the neutral charge state uses the nomenclature NV⁰, while the negative charge state uses the nomenclature NV, which is adopted in this description.

The NV center has a number of electrons including three unpaired electrons, each one from the vacancy to a respective of the three carbon atoms adjacent to the vacancy, and a pair of electrons between the nitrogen and the vacancy. The NV center, which is in the negatively charged state, also includes an extra electron.

The NV center has rotational symmetry, and as shown in FIG. 2, has a ground state, which is a spin triplet with ³A₂ symmetry with one spin state mₛ=0, and two further spin states mₛ=+1, and mₛ=−1. In the absence of an external magnetic field, the mₛ=±1 energy levels are offset from the mₛ=0 due to spin-spin interactions, and the mₛ=±1 energy levels are degenerate, i.e., they have the same energy. The mₛ=0 spin state energy level is split from the mₛ=±1 energy levels by a energy of 2.87 GHz for a zero external magnetic field.

Introducing an external magnetic field with a component along the NV axis lifts the degeneracy of the mₛ=±1 energy levels, splitting the energy levels mₛ=±1 by an amount 2 gμ_{B}Bz, where g is the g-factor, μ_{B} is the Bohr magneton, and Bz is the component of the external magnetic field along the NV axis. This relationship is correct to a first order and inclusion of higher order corrections is a straightforward matter and should not affect the computational and logic steps in the systems and methods described below.

The NV center electronic structure further includes an excited triplet state ³E with corresponding mₛ=0 and mₛ=±1 spin states. The optical transitions between the ground state ³A₂ and the excited triplet ³E are predominantly spin conserving, meaning that the optical transitions are between initial and final states which have the same spin. For a direct transition between the excited triplet ³E and the ground state ³A₂, a photon of red light is emitted with a photon energy corresponding to the energy difference between the energy levels of the transitions.

There is, however, an alternate non-radiative decay route from the triplet ³E to the ground state ³A₂ via intermediate electron states, which are thought to be intermediate singlet states A, E with intermediate energy levels. Significantly, the transition rate from the mₛ=±1 spin states of the excited triplet ³E to the intermediate energy levels is significantly greater than that from the mₛ=0 spin state of the excited triplet ³E to the intermediate energy levels. The transition from the singlet states A, E to the ground state triplet ³A₂ predominantly decays to the mₛ=0 spin state over the mₛ=±1 spin states. These features of the decay from the excited triplet ³E state via the intermediate singlet states A, E to the ground state triplet ³A₂ allows that if optical excitation is provided to the system, the optical excitation will eventually pump the NV center into the mₛ=0 spin state of the ground state ³A₂. In this way, the population of the mₛ=0 spin state of the ground state ³A₂ may be “reset” to a maximum polarization determined by the decay rates from the triplet ³E to the intermediate singlet states.

Another feature of the decay is that the fluorescence intensity due to optically stimulating the excited triplet ³E state is less for the mₛ=±1 states than for the mₛ=0 spin state. This is so because the decay via the intermediate states does not result in a photon emitted in the fluorescence band, and because of the greater probability that the mₛ=±1 states of the excited triplet ³E state will decay via the non-radiative decay path. The lower fluorescence intensity for the mₛ=±1 states than for the mₛ=0 spin state allows the fluorescence intensity to be used to determine the spin state. As the population of the mₛ=±1 states increases relative to the mₛ=0 spin, the overall fluorescence intensity will be reduced.

NV Center, or Magneto-Optical Defect Center, Magnetic Sensor System

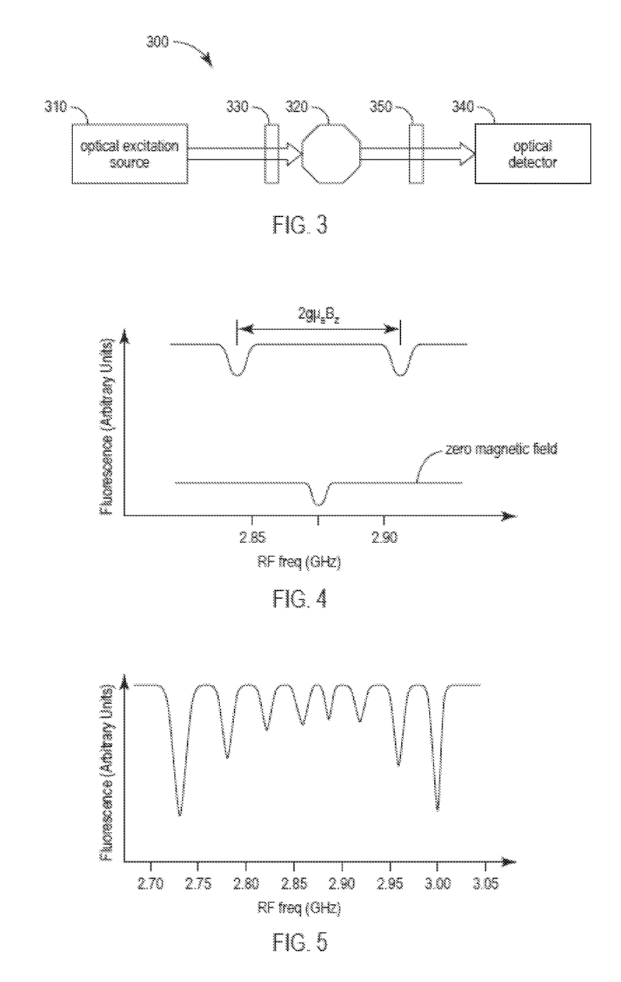

FIG. 3 is a schematic illustrating a NV center magnetic sensor system 300 which uses fluorescence intensity to distinguish the mₛ=±1 states, and to measure the magnetic field based on the energy difference between the mₛ=+1 state and the mₛ=−1 state. The system 300 includes an optical excitation source 310, which directs optical excitation to an NV diamond material 320 with NV centers. The system 300 further includes an RF excitation source 330 which provides RF radiation to the NV diamond material 320. Light from the NV diamond may be directed through an optical filter 350 to an optical detector 340.

The RF excitation source 330 may be a microwave coil, for example. The RF excitation source 330 when emitting RF radiation with a photon energy resonant with the transition energy between ground mₛ=0 spin state and the mₛ=+1 spin state excites a transition between those spin states. For such a resonance, the spin state cycles between ground mₛ=0 spin state and the mₛ=+1 spin state, reducing the population in the mₛ=0 spin state and reducing the overall fluorescence at resonance. Similarly resonance occurs between the mₛ=0 spin state and the mₛ=−1 spin state of the ground state when the photon energy of the RF radiation emitted by the RF excitation source is the difference in energies of the mₛ=0 spin state and the mₛ=−1 spin state. At resonance between the mₛ=0 spin state and the mₛ=−1 spin state, or between the mₛ=0 spin state and the mₛ=+1 spin state, there is a decrease in the fluorescence intensity.

The optical excitation source 310 may be a laser or a light emitting diode, for example, which emits light in the green, for example. The optical excitation source 310 induces fluorescence in the red, which corresponds to an electronic transition from the excited state to the ground state. Light from the NV diamond material 320 is directed through the optical filter 350 to filter out light in the excitation band (in the green for example), and to pass light in the red fluorescence band, which in turn is detected by the detector 340. The optical excitation light source 310, in addition to exciting fluorescence in the diamond material 320, also serves to reset the population of the mₛ=0 spin state of the ground state ³A₂ to a maximum polarization, or other desired polarization.

For continuous wave excitation, the optical excitation source 310 continuously pumps the NV centers, and the RF excitation source 330 sweeps across a frequency range which includes the zero splitting (when the mₛ=±1 spin states have the same energy) photon energy of 2.87 GHz. The fluorescence for an RF sweep corresponding to a diamond material 320 with NV centers aligned along a single direction is shown in FIG. 4 for different magnetic field components Bz along the NV axis, where the energy splitting between the mₛ=−1 spin state and the mₛ=+1 spin state increases with Bz. Thus, the component Bz may be determined. Optical excitation schemes other than continuous wave excitation are contemplated, such as excitation schemes involving pulsed optical excitation, and pulsed RF excitation. Examples, of pulsed excitation schemes include Ramsey pulse sequence, and spin echo pulse sequence.

In general, the diamond material 320 will have NV centers aligned along directions of four different orientation classes. FIG. 5 illustrates fluorescence as a function of RF frequency for the case where the diamond material 320 has NV centers aligned along directions of four different orientation classes. In this case, the component Bz along each of the different orientations may be determined. These results along with the known orientation of crystallographic planes of a diamond lattice allows not only the magnitude of the external magnetic field to be determined, but also the direction of the magnetic field.

While FIG. 3 illustrates an NV center magnetic sensor system 300 with NV diamond material 320 with a plurality of NV centers, in general the magnetic sensor system may instead employ a different magneto-optical defect center material, with a plurality of magneto-optical defect centers. The electronic spin state energies of the magneto-optical defect centers shift with magnetic field, and the optical response, such as fluorescence, for the different spin states is not the same for all of the different spin states. In this way, the magnetic field may be determined based on optical excitation, and possibly RF excitation, in a corresponding way to that described above with NV diamond material.

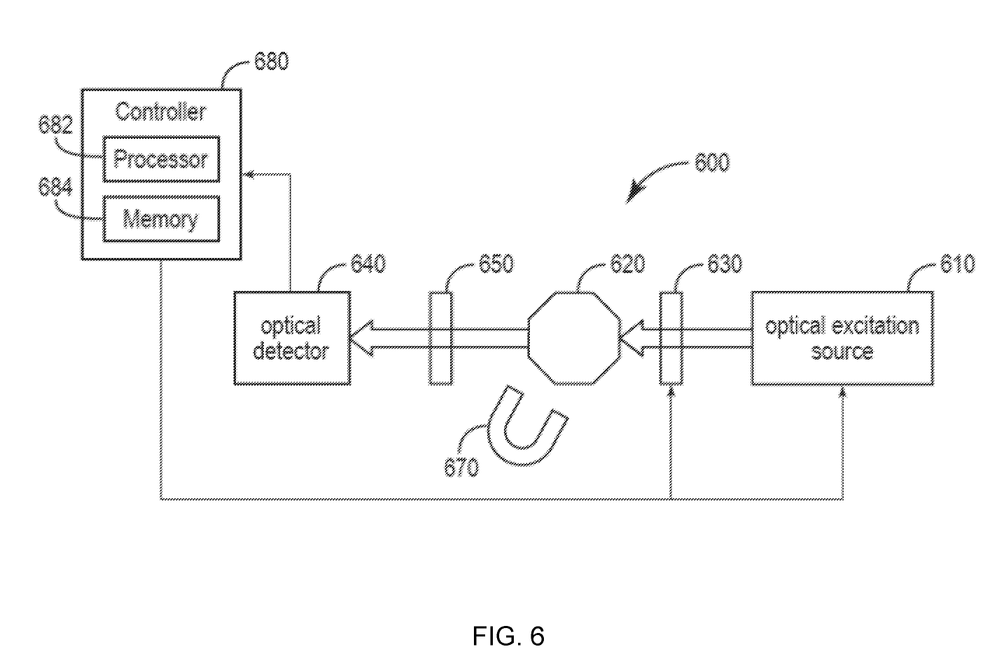

FIG. 6 is a schematic of an NV center magnetic sensor 600, according to some embodiments. The sensor 600 includes an optical excitation source 610, which directs optical excitation to an NV diamond material 620 with NV centers, or another magneto-optical defect center material with magneto-optical defect centers. An RF excitation source 630 provides RF radiation to the NV diamond material 620. The NV center magnetic sensor 600 may include a bias magnet 670 applying a bias magnetic field to the NV diamond material 620. Light from the NV diamond material 620 may be directed through an optical filter 650 and an electromagnetic interference (EMI) filter 660, which suppresses conducted interference, to an optical detector 640. The sensor 600 further includes a controller 680 arranged to receive a light detection signal from the optical detector 640 and to control the optical excitation source 610 and the RF excitation source 630.

The RF excitation source 630 may be a microwave coil, for example. The RF excitation source 630 is controlled to emit RF radiation with a photon energy resonant with the transition energy between the ground mₛ=0 spin state and the mₛ=±1 spin states as discussed above with respect to FIG. 3.

The optical excitation source 610 may be a laser or a light emitting diode, for example, which emits light in the green, for example. The optical excitation source 610 induces fluorescence in the red, which corresponds to an electronic transition from the excited state to the ground state. Light from the NV diamond material 620 is directed through the optical filter 650 to filter out light in the excitation band (in the green for example), and to pass light in the red fluorescence band, which in turn is detected by the optical detector 640. The EMI filter 660 is arranged between the optical filter 650 and the optical detector 640 and suppresses conducted interference. The optical excitation light source 610, in addition to exciting fluorescence in the NV diamond material 620, also serves to reset the population of the mₛ=0 spin state of the ground state ³A₂ to a maximum polarization, or other desired polarization.

The controller 680 is arranged to receive a light detection signal from the optical detector 640 and to control the optical excitation source 610 and the RF excitation source 630. The controller may include a processor 682 and a memory 684, in order to control the operation of the optical excitation source 610 and the RF excitation source 630. The memory 684, which may include a nontransitory computer readable medium, may store instructions to allow the operation of the optical excitation source 610 and the RF excitation source 630 to be controlled.

According to some embodiments of operation, the controller 680 controls the operation such that the optical excitation source 610 continuously pumps the NV centers of the NV diamond material 620. The RF excitation source 630 is controlled to continuously sweep across a frequency range which includes the zero splitting (when the mₛ=±1 spin states have the same energy) photon energy of 2.87 GHz. When the photon energy of the RF radiation emitted by the RF excitation source 630 is the difference in energies of the mₛ=0 spin state and the mₛ=−1 or mₛ=+1 spin state, the overall fluorescence intensity is reduced at resonance, as discussed above with respect to FIG. 3. In this case, there is a decrease in the fluorescence intensity when the RF energy resonates with an energy difference of the mₛ=0 spin state and the mₛ=−1 or mₛ=+1 spin states. In this way the component of the magnetic field Bz along the NV axis may be determined by the difference in energies between the mₛ=−1 and the mₛ=+1 spin states.

As noted above, the diamond material 620 will have NV centers aligned along directions of four different orientation classes, and the component Bz along each of the different orientations may be determined based on the difference in energy between the mₛ=−1 and the mₛ=+1 spin states for the respective orientation classes. In certain cases, however, it may be difficult to determine which energy splitting corresponds to which orientation class, due to overlap of the energies, etc. The bias magnet 670 provides a magnetic field, which is preferably uniform on the NV diamond material 620, to separate the energies for the different orientation classes, so that they may be more easily identified.

Natural Ambiguity of NV Center Magnetic Sensor System

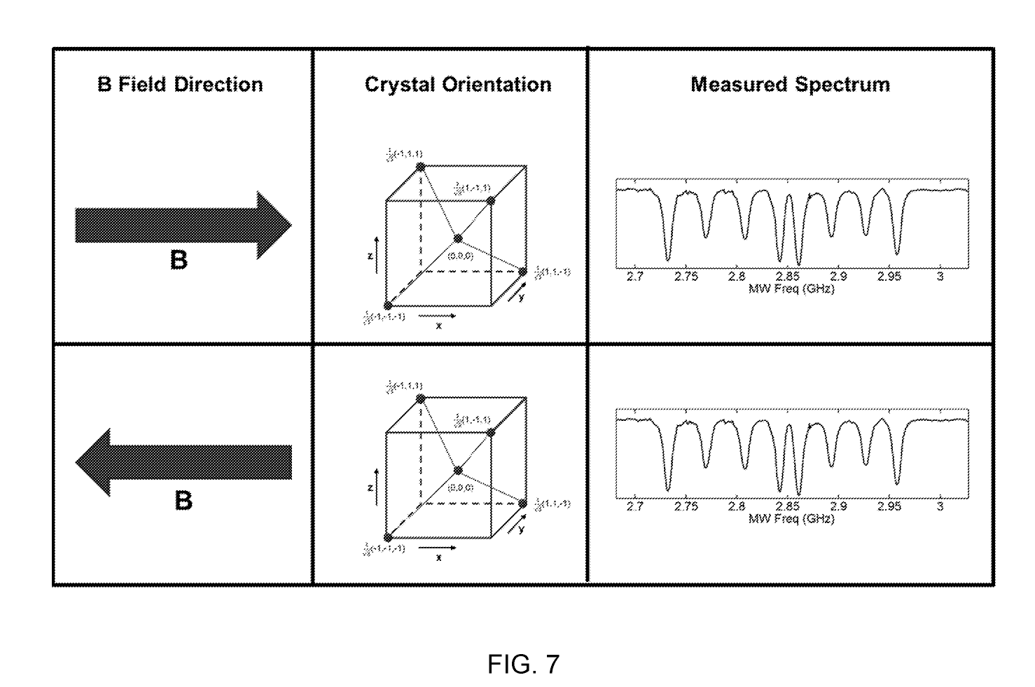

The NV center magnetic sensor that operates as described above is capable of resolving a magnetic field to an unsigned vector. As shown in FIG. 7, due to the symmetry of the peaks for the mₛ=−1 and the mₛ=+1 spin states around the zero splitting photon energy the structure of the DNV material produces a measured fluorescence spectrum as a function of RF frequency that is the same for a positive and a negative magnetic field acting on the DNV material. The symmetry of the fluorescence spectra makes the assignment of a sign to the calculated magnetic field vector unreliable. The natural ambiguity introduced to the magnetic field sensor is undesirable in some applications, such as magnetic field based direction sensing.

In some circumstances, real world conditions allow the intelligent assignment of a sign to the unsigned magnetic field vector determined from the fluorescence spectra described above. If a known bias field is used that is much larger than the signal of interest, the sign of the magnetic field vector may be determine by whether the total magnetic field, cumulative of the bias field and the signal of interest, increases or decreases. If the magnetic sensor is employed to detect submarines from a surface ship, assigning the calculated magnetic field vector a sign that would place a detected submarine above the surface ship would be nonsensical. Alternatively, where the sign of the vector is not important a sign can be arbitrarily assigned to the unsigned vector.

It is possible to unambiguously determine a magnetic field vector with a DNV magnetic field sensor. The method of determining the signed magnetic field vector may be performed with a DNV magnetic field sensor of the type shown in FIG. 6 and described above. In general, the recovery of the vector may be achieved as described in co-pending U.S. application Ser. No. ______, filed Jan. 21, 2016, titled “APPARATUS AND METHOD FOR RECOVERY OF THREE DIMENSIONAL MAGNETIC FIELD FROM A MAGNETIC DETECTION SYSTEM”, which is incorporated by reference herein in its entirety.

As shown in FIG. 2, the energy levels of the mₛ=−1 and the mₛ=+1 spin states are different. For this reason, the relaxation times from the excited triplet states (³E) to the excited intermediate singlet state (A) for electrons with the mₛ=−1 and the mₛ=+1 spin states are not the same. The difference in relaxation times for electrons of mₛ=−1 and the mₛ=+1 spin states is on the order of picoseconds or nanoseconds. It is possible to measure the difference in relaxation times for the electrons with the mₛ=−1 and the mₛ=+1 spin states by utilizing pulsed RF excitation such that the inequality in the relaxation times accumulates over a large number of electron cycles, producing a difference in observed relaxation times on the order of microseconds.

As described above, the application of RF excitation to the DNV material produces a decrease in fluorescence intensity at the resonant RF frequencies for the mₛ=−1 and the mₛ=+1 spin states. For this reason, at RF frequencies that excite electrons to the mₛ=−1 and the mₛ=+1 spin states, an equilibrium fluorescence intensity will be lower than the equilibrium fluorescence intensity in the absence of the applied RF excitation. The time it takes to transition from the equilibrium fluorescence intensity in the absence of RF excitation to the equilibrium fluorescence intensity with the application of RF excitation may be employed to calculate an “equilibration time.”

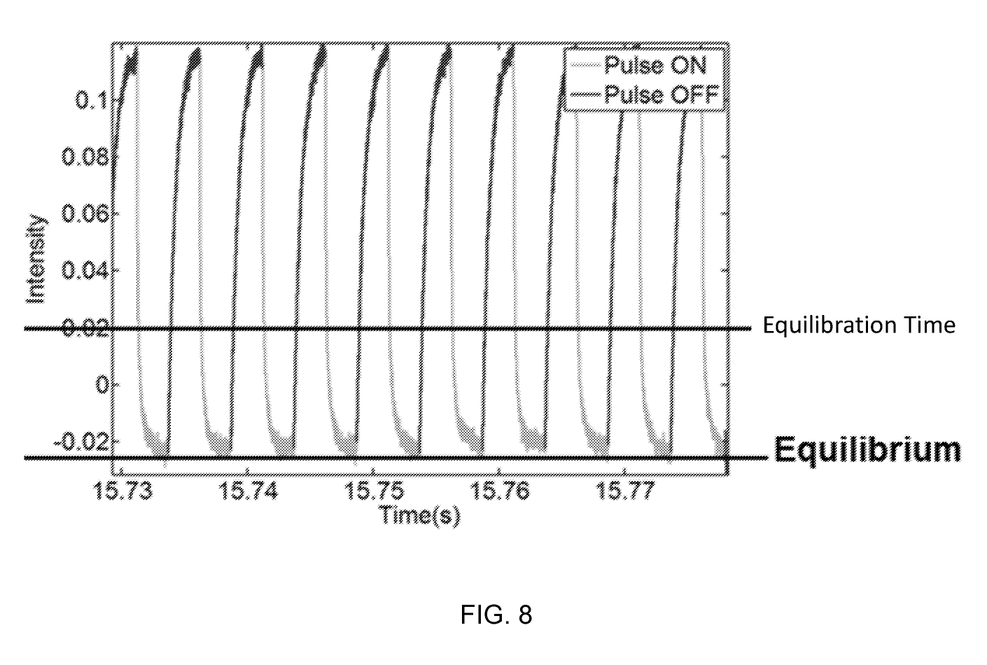

An “equilibration time” as utilized herein refers to the time between the start of an RF excitation pulse and when a predetermined percentage of the equilibrium fluorescence intensity is achieved. The predetermined amount of the equilibrium fluorescence at which the equilibration time is calculated may be about 20% to about 80% of the equilibrium fluorescence, such as about 30%, 40%, 50%, 60%, or 70% of the equilibrium fluorescence. The equilibration time as shown in FIGS. 8, 10 and 11 is actually a decay time, as the fluorescence intensity is actually decreasing in the presence of the RF excitation, but has been inverted for the sake of clarity.

A shown in FIG. 8, the fluorescence intensity of the DNV material varies with the application of a pulsed RF excitation source. When the RF pulse is in the “on” state, the electrons decay through a non-fluorescent path and a relatively dark equilibrium fluorescence is achieved. The absence of the RF excitation, when the pulse is in the “off” state, results in a relatively bright equilibrium fluorescence. The transition between the two fluorescence equilibrium states is not instantaneous, and the measurement of the equilibration time at a predetermined value of fluorescence intensity provides a repeatable indication of the relaxation time for the electrons at the RF excitation frequency.

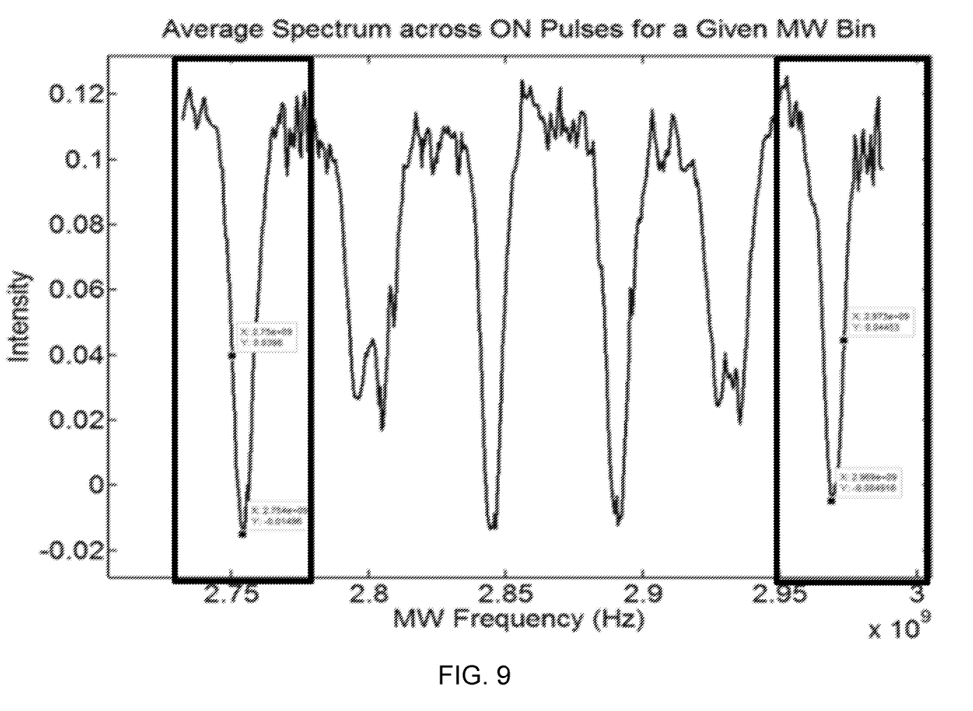

The difference in the relaxation time between the electrons of the mₛ=−1 and the mₛ=+1 spin states may be measured due to the different RF excitation resonant frequencies for each spin state. As shown in FIG. 9, a fluorescence intensity spectra of the DNV material measured as a function of RF excitation frequency includes four Lorentzian pairs, one pair for each crystallographic plane of the DNV material. The peaks in a Lorentzian pair correspond to a mₛ=−1 and a mₛ=+1 spin state. By evaluating the equilibration time for each peak in a Lorentzian pair, the peak which corresponds to the higher energy state may be identified. The higher energy peak provides a reliable indication of the sign of the magnetic field vector.

The Lorentzian pair of the fluorescence spectra which are located furthest from the zero splitting energy may be selected to calculate the equilibration time. These peaks include the least signal interference and noise, allowing a more reliable measurement. The preferred Lorentzian pair is boxed in FIG. 9.

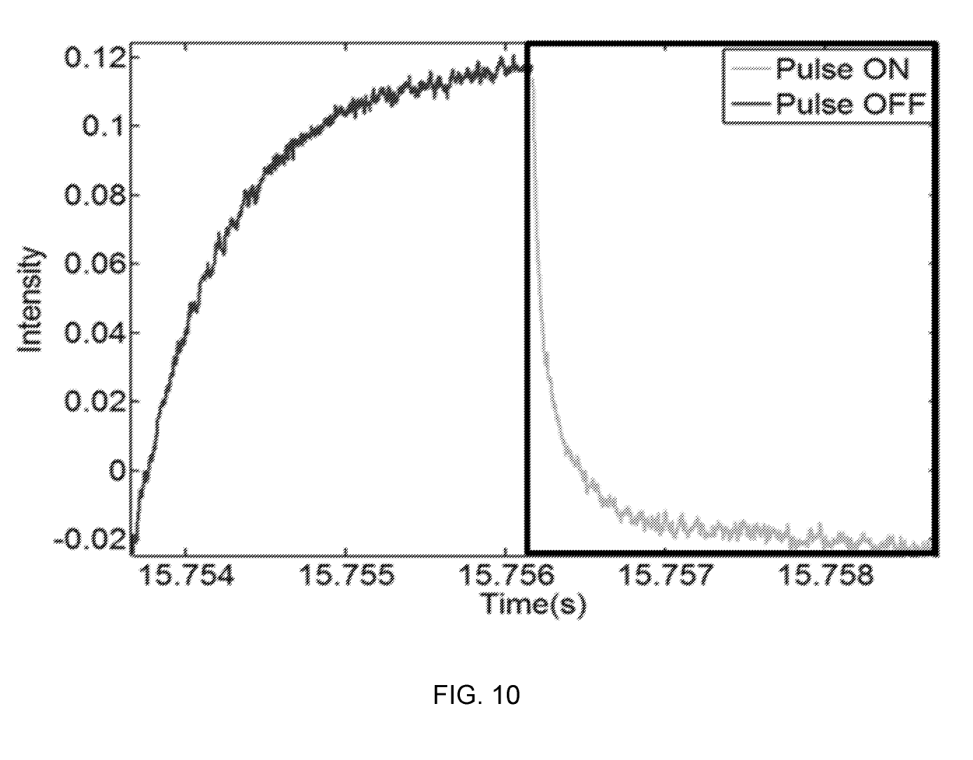

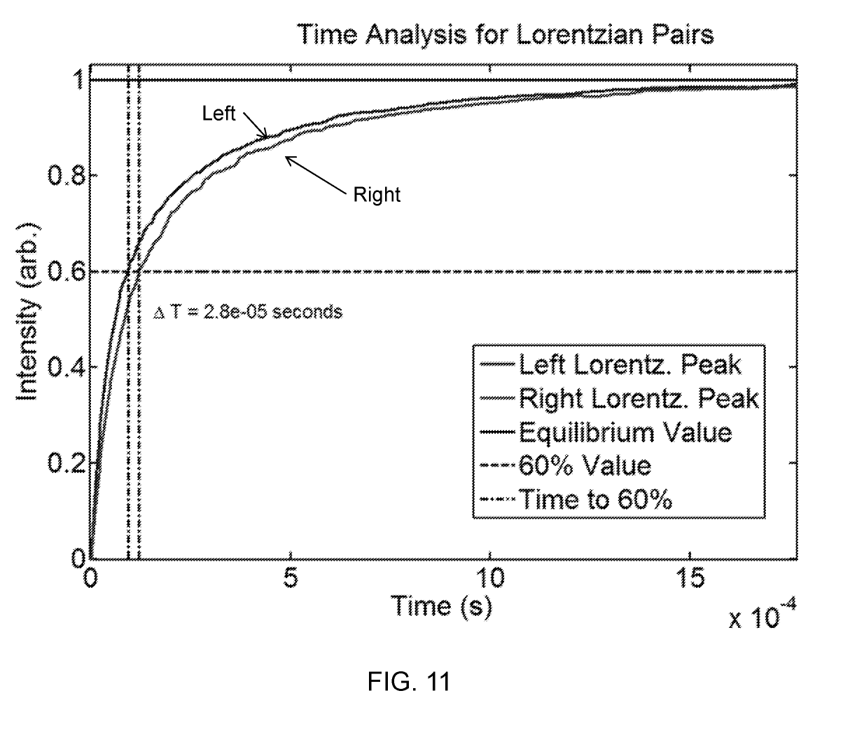

A plot of the fluorescence intensity for a single RF pulse as a function of time is shown in FIG. 10. The frequency of the pulsed RF excitation is selected to be the maximum value for each peak in the Lorentzian pair. The other conditions for the measurement of an equilibration time for each peak in the Lorentzian pair are held constant. As shown in FIG. 11, the peaks of the Lorentzian pair have an equilibration time when calculated to 60% of the equilibrium intensity value that is distinguishable. The RF pulse duration may be set such that the desired percentage of the equilibrium fluorescence intensity is achieved for each “on” portion of the pulse, and the full “bright” equilibrium intensity is achieved during the “off” portion of the pulse.

The equilibrium fluorescence intensity under the application of the RF excitation may be set by any appropriate method. According to some embodiments, the RF excitation may be maintained until the intensity becomes constant, and the constant intensity may be considered the equilibrium intensity value utilized to calculate the equilibration time. Alternatively, the equilibrium intensity may be set to the intensity at the end of an RF excitation pulse. According to other embodiments, a decay constant may be calculated based on the measured fluorescence intensity and a theoretical data fit employed to determine the equilibrium intensity value.

The peak in the Lorentzian pair that exhibits the higher measured equilibration time is associated with the higher energy level electron spin state. For this reason, the peak of the Lorentzian pair with the longer equilibration time is assigned the mₛ=+1 spin state, and the other peak in the Lorentzian pair is assigned the mₛ=−1 spin state. The signs of the peaks in the other Lorentzian pairs in the fluorescence spectra of the DNV material as a function of RF frequency may then be assigned, and the signed magnetic field vector calculated.

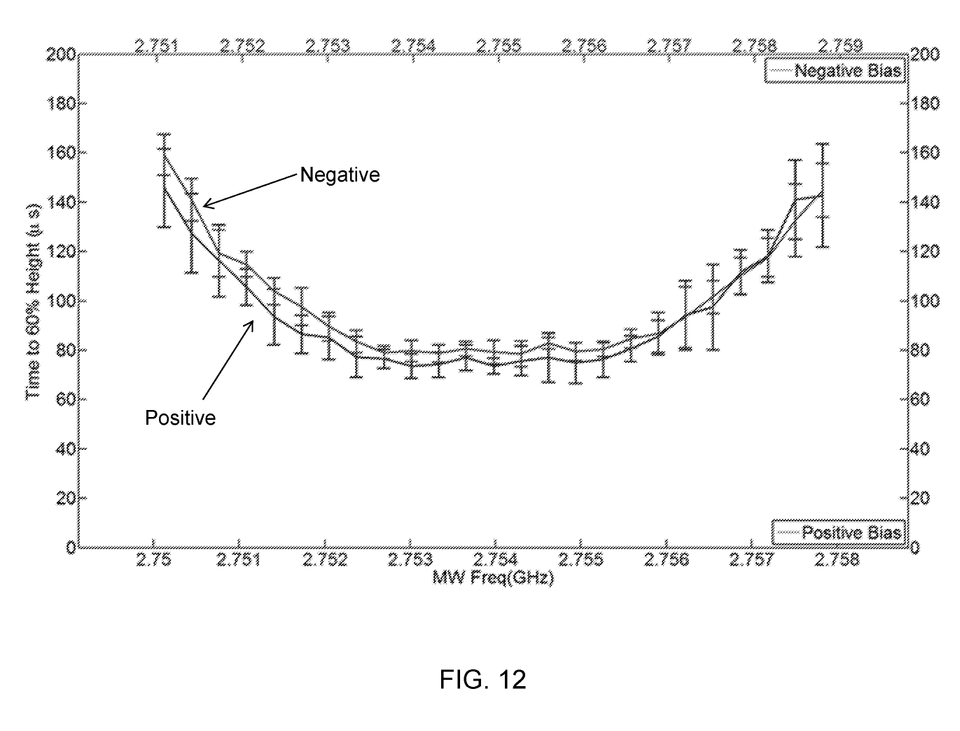

To demonstrate that the equilibration time of each peak in a Lorentzian pair does indeed vary with magnetic field direction, the equilibration time for a single peak in a Lorentzian pair was measured under both a positive and a negative magnetic bias field which were otherwise equivalent. As shown in FIG. 12, a real and measurable difference in equilibration time was observed between the opposite bias fields.

The method of determining a sign of a magnetic field vector with a DNV magnetic sensor described herein may be performed with the DNV magnetic field sensor shown in FIG. 6. No additional hardware is required.

The controller of the magnetic field sensor may be programmed to determine the location of peaks in a fluorescence spectra of a DNV material as a function of RF frequency. The equilibration time for the peaks of a Lorentzian pair located the furthest from the zero field energy may then be calculated. The controller may be programmed to provide a pulsed RF excitation energy by controlling a RF excitation source and also control an optical excitation source to excite the DNV material with continuous wave optical excitation. The resulting optical signal received at the optical detector may be analyzed by the controller to determine the equilibration time associated with each peak in the manner described above. The controller may be programmed to assign a sign to each peak based on the measured equilibration time. The peak with the greater measured equilibration time may be assigned the mₛ=+1 spin state.

The method of assigning a sign to a magnetic field vector described above may also be applied to magnetic field sensors based on magneto-optical defect center materials other than DNV.

The DNV magnetic field sensor described herein that produces a signed magnetic field vector may be especially useful in applications in which the direction of a measured magnetic field is important. For example, the DNV magnetic field sensor may be employed in magnetic field based navigation or positioning systems.

The embodiments of the concepts disclosed herein have been described in detail with particular reference to preferred embodiments thereof, but it will be understood by those skilled in the art that variations and modifications can be effected within the spirit and scope of the described concepts.

What is claimed is:

1. A system comprising:
a nitrogen vacancy (NV) diamond material comprising a plurality of NV centers;
a magnetic field source;
a radio frequency (RF) excitation source configured to provide RF excitation to the NV diamond material;
an optical excitation source configured to provide optical excitation to the NV diamond material;
an optical detector configured to receive an optical signal emitted by the NV diamond material; and
a controller configured to:
determine a first equilibration time for a first peak of a Lorentzian pair based on a received light detection signal from the optical detector,
determine a second equilibration time for a second peak of the Lorentzian pair based on a received light detection signal from the optical detector, and
determine a sign of the magnetic field vector at the NV diamond material based on the first equilibration time and the second equilibration time.

2. The system of claim 1, wherein the controller is configured to assign a positive spin state to the peak of the Lorentzian pair with the longer equilibration time.

3. The system of claim 1, wherein the first equilibration time and the second equilibration time are determined by measuring the time to reach 60% of a normalized equilibrium intensity after the beginning of an RF pulse, wherein the normalized equilibrium intensity is determined based on the intensity in the absence of the RF pulse and the equilibrium intensity in the presence of the RF pulse.

4. A system, comprising:
a nitrogen vacancy (NV) diamond material comprising a plurality of NV centers;
a magnetic field source;
a radio frequency (RF) excitation source configured to provide RF excitation to the NV diamond material;
an optical excitation source configured to provide optical excitation to the NV diamond material;
an optical detector configured to receive an optical signal emitted by the NV diamond material; and
a controller configured to:
control the RF excitation source to provide pulsed RF excitation to the NV diamond material, and
determine a sign of the magnetic field vector at the NV diamond material based on a received light detection signal from the optical detector.

5. The system of claim 4, wherein the controller is configured to control the optical excitation source to provide continuous wave optical excitation to the NV diamond.

6. The system of claim 4, wherein the controller is further configured to identify Lorentzian peaks in a received light detection signal from the optical detector as a function of RF excitation frequency.

7. The system of claim 6, wherein the controller is configured to determine a sign of the magnetic field vector based on an equilibration time for a pair of the identified Lorentzian peaks.

8. A system, comprising:
a magneto-optical defect center material;
a magnetic field source;
a radio frequency (RF) excitation source configured to provide RF excitation to the magneto-optical defect center material;
an optical excitation source configured to provide optical excitation to the magneto-optical defect center material;
an optical detector configured to receive an optical signal emitted by the magneto-optical defect center material; and
a controller configured to:
control the RF excitation source to provide pulsed RF excitation to the magneto-optical defect center material,
control the optical excitation source to provide optical excitation to the magneto-optical defect center material, and
determine a sign of the magnetic field vector at the magneto-optical defect center material based on a received light detection signal from the optical detector.

9. The system of claim 8, wherein the controller is configured to control the optical excitation source to provide continuous wave optical excitation to the magneto-optical defect center material.

10. The system of claim 8, wherein the controller is further configured to identify Lorentzian peaks in a received light detection signal from the optical detector as a function of RF excitation frequency.

11. The system of claim 10, wherein the controller is configured to determine a sign of the magnetic field vector based on an equilibration time for a pair of the identified Lorentzian peaks.
